(19) United States
(12) Patent Application Publication
(10) Pub. No.: US 2013/0134475 A1
(43) Pub. Date: May 30, 2013

(54) SEMICONDUCTOR LIGHT EMITTING DEVICE

(71) Applicant: Samsung Electronics Co., Ltd., Gyeonggi-do (KR)

(72) Inventors: Sang Heon HAN, Gyeonggi-do (KR); Jae Sung HYUN, Seoul (KR); Jin Young LIM, Gyeonggi-do (KR); Jeong Wook LEE, Gyeonggi-do (KR); Young Sun KIM, Gyeonggi-do (KR)

(73) Assignee: SAMSUNG ELECTRONICS CO., LTD., Gyeonggi-do (KR)

(21) Appl. No.: 13/684,406

(22) Filed: Nov. 23, 2012

(30) Foreign Application Priority Data
Nov. 25, 2011 (KR) 10-2011-0124397

(51) Int. Cl. H01L 33/00

(52) U.S. Cl. CPC H01L 33/0025
USPC 257/101

(57) ABSTRACT

A semiconductor light emitting device is provided and includes an n-type semiconductor layer, a p-type semiconductor layer having a structure in which first and second doping regions including p-type impurities provided in different doping concentrations are alternately disposed one or more times; and an active layer disposed between the n-type semiconductor layer and the p-type semiconductor layer, wherein the p-type semiconductor layer includes at least one interface between the first and second doping regions to prevent diffusion of p-type impurities.

### CROSS-REFERENCE TO RELATED APPLICATIONS

This application claims the priority of Korean Patent Application No. 10-2011-0124397 filed on Nov. 25, 2011, in the Korean Intellectual Property Office, the disclosure of which is incorporated herein by reference.

### TECHNICAL FIELD

The present application relates to a semiconductor light emitting device.

### BACKGROUND

A light emitting diode (LED), a type of a semiconductor light emitting device, is a semiconductor device that can emit light of various colors due to electron-hole recombination occurring at a p-n junction in the semiconductor device when a current is supplied thereto. Compared to light emitting devices based on filaments, such semiconductor light emitting devices have much strength such as a long lifespan, low power consumption, and excellent initial operating characteristics. Hence, demand for semiconductor light emitting devices is continuously increasing. In particular, recently, group III nitride semiconductors that can emit short wavelength light in the blue region of the spectrum have recently drawn a lot of attention.

An LED is operated by applying electrical signals to electrodes having different polarities. In this regard, current tends to be concentrated on and to flow in a region including an electrode or having low resistance. Thus, a current flows narrowly, and thus, an operating voltage ‘Vf’ of a light emitting device may be increased due to a narrow flow of current. Furthermore, a light emitting device may become vulnerable to electrostatic discharges. In order to solve this defect, in the art to which the present application pertains, many methods have been suggested in order to improve a current diffusing function.

As a method of improving a current diffusing function, a current blocking layer may be disposed in a semiconductor layer so as to allow current to flow in a lateral direction. However, additional processes are required to insert impurities, for example, a dielectric material such as SiO₂ or the like into a nitride semiconductor and the crystallinity of the nitride semiconductor may be adversely affected by the current blocking layer. In addition, in spite of the current blocking layer, it may not be sufficient to allow current to flow in a lateral direction with regard to a hole.

A need still remains for a semiconductor light emitting device that significantly reduces defects due to current concentration by obtaining an effect of dispersing holes in a lateral direction.

### SUMMARY

An aspect of the present application provides a semiconductor light emitting device able to significantly reduce defects due to current concentration by obtaining an effect of dispersing holes in a lateral direction. However, the present application should not be construed as being limited to the objective described herein and may include objectives and effects that are known from the detailed description although not clearly indicated herein.

According to an aspect of the present application, there is provided a semiconductor light emitting device including an n-type semiconductor layer; a p-type semiconductor layer having a structure in which first and second doping regions including p-type impurities provided in different doping concentrations are alternately disposed one or more times; and an active layer disposed between the n-type semiconductor layer and the p-type semiconductor layer, wherein the p-type semiconductor layer includes at least one interface between the first and second doping regions. The at least one interface is doped with n-type impurities.

The first doping region may have a higher doping concentration of p-type impurities than the second doping region.

The first doping region may have higher bandgap energy than the second doping region.

The first doping region may include a region formed of AlₓIn_{y}Ga_{1-x-y}N (0<x≦1 and 0≦y<1), and the second doping region may include a region formed of AlₐIn_{b}Ga_{1-a-b}N (0≦a<x and 0≦b≦1).

In addition, the p-type semiconductor layer may have a superlattice structure in which the first and second doping regions are alternately disposed two or more times.

The p-type semiconductor layer may include a clad layer having lower bandgap energy than the first doping region, and the superlattice structure may be disposed between the active layer and the clad layer.

The first doping region may include a region formed of AlₓIn_{y}Ga_{1-x-y}N (0<x≦1 and 0≦y<1), and the clad layer may include a region formed of AlₐIn_{b}Ga_{1-a-b}N (0≦a<x and 0≦b≦1).

In addition, the first and second doping regions may have the same amount of bandgap energy.

The p-type semiconductor layer may include an electron blocking layer that is disposed to be adjacent to the active layer and has higher bandgap energy than the first and second doping regions.

The electron blocking layer may include a region formed of AlₓIn_{y}Ga_{1-x-y}N (0<x≦1 and 0≦y<1), and the first and second doping regions may include a region formed of AlₐIn_{b}Ga_{1-a-b}N (0≦a<x and 0≦b≦1).

In addition, the second doping region may include p-type impurities and may not be intentionally doped.

The interface between the first and second doping regions that are doped with the n-type impurities may be doped with p-type impurities.

The n-type impurities may include at least one of silicon (Si) and carbon (C), and the p-type impurities may include at least one of magnesium (Mg) and zinc (Zn). According to another aspect of the present application, a semiconductor light emitting device is provided. The device includes a first type semiconductor layer and a second type semiconductor layer having a structure in which first and second doping regions including second type impurities provided in different doping concentrations are alternately disposed one or more times. A diffusion barrier region is disposed at an interface between the first and second doping regions to prevent diffusion of the second type impurities. An active layer is disposed between the first type semiconductor layer and the second type semiconductor layer.

Additional advantages and novel features will be set forth in part in the description which follows, and in part will become apparent to those skilled in the art upon examination of the following and the accompanying drawings or may be learned by production or operation of the examples. The advantages of the present teachings may be realized and attained by practice or use of various aspects of the methodologies, instrumentalities and combinations set forth in the detailed examples discussed below.

### BRIEF DESCRIPTION OF THE DRAWINGS

The drawing figures depict one or more implementations in accord with the present teachings, by way of example only, not by way of limitation. In the figures, like reference numerals refer to the same or similar elements.

FIG. 1 is a schematic cross-sectional view of a semiconductor light emitting device according to an example of the present application;

FIG. 2 is an enlarged view of an electron blocking layer that may be included in the semiconductor light emitting device of FIG. 1, according to an example of the present application;

FIG. 3 is a diagram of an energy band around the electron blocking layer of FIG. 2, according to an example of the present application;

FIG. 4 is a schematic cross-sectional view of a semiconductor light emitting device according to another example of the present application;

FIG. 5 is an enlarged view of a clad layer that may be used in the semiconductor light emitting device of FIG. 4, according to an example of the present application;

FIG. 6 is a diagram of an energy band around the clad layer of FIG. 5, according to an example of the present application;

FIG. 7 is a graph showing a relationship between a driving voltage Vf and light emitting power Po, in semiconductor light emitting devices according to an inventive example and a comparative example; and

FIG. 8 is a schematic cross-sectional view of a nitride semiconductor light emitting device according to another example of the present application.

### DETAILED DESCRIPTION

In the following detailed description, numerous specific details are set forth by way of examples in order to provide a thorough understanding of the relevant teachings. However, it should be apparent to those skilled in the art that the present teachings may be practiced without such details. In other instances, well known methods, procedures, components, and/or circuitry have been described at a relatively high-level, without detail, in order to avoid unnecessarily obscuring aspects of the present teachings.

The present application will now be described more fully with reference to the accompanying drawings, in which examples of the application are shown.

The application may, however, be embodied in many different forms and should not be construed as being limited to the examples set forth herein; rather, these examples may be provided so that this disclosure will be thorough and complete, and will fully convey the concept of the application to those skilled in the art. In the drawings, the shapes and sizes of elements may be exaggerated for clarity.

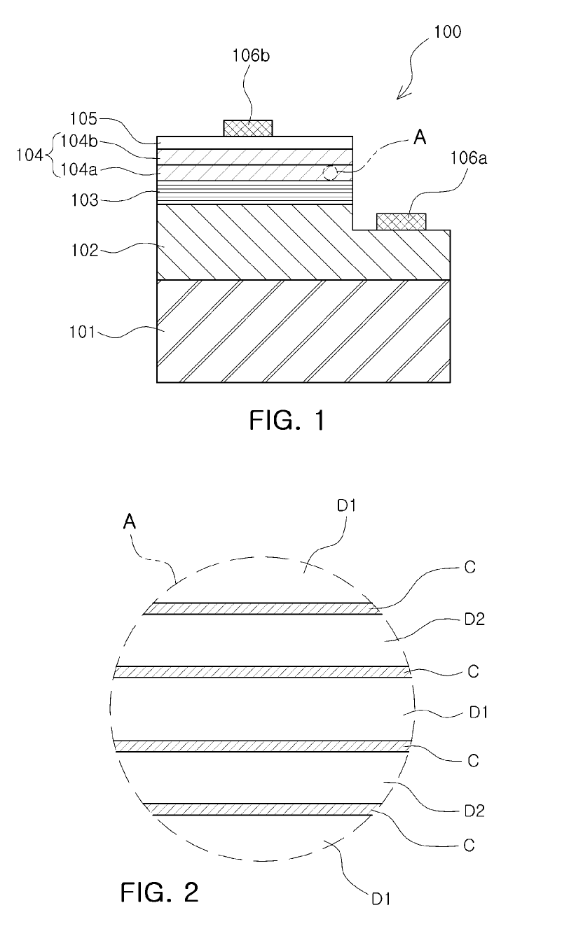

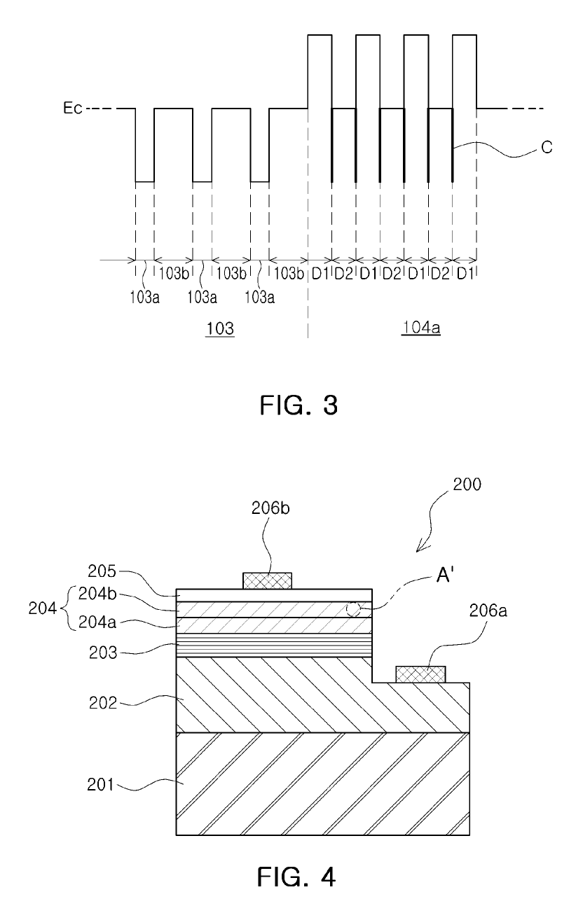

FIG. 1 is a schematic cross-sectional view of a semiconductor light emitting device 100 according to an example of the present application. FIG. 2 is an enlarged view of an electron blocking layer 104a that may be included in the semiconductor light emitting device 100 of FIG. 1, according to an example of the present application. FIG. 3 is a diagram of an energy band around the electron blocking layer 104a of FIG. 2, according to an example of the present application. Referring to FIG. 1, the semiconductor light emitting device 100 according to the present example includes a substrate 101, an n-type semiconductor layer 102, an active layer 103, a p-type semiconductor layer 104, and an ohmic electrode layer 105. First and second electrodes 106a and 106b may be formed on upper surfaces of the n-type semiconductor layer 102 and the ohmic electrode layer 105, respectively. In this case, the p-type semiconductor layer 104 may have a structure including the electron blocking layer 104a and a clad layer 104b. However, throughout this specification, the terms ‘on’, ‘upper surface’, ‘below’, ‘lower surface’, ‘lateral surface’ and so on are used with respect to the drawings, and thus, may be different in reality according to a direction in which a component is disposed. With regard to the subscripts ‘x’, ‘y’, ‘z’, ‘a’, ‘b’, and so on that are used in formulae shown below, when a subscript is used in different materials, it is to be understood that there is no relationship therebetween, in spite of the same subscript, unless otherwise indicated.

The substrate 101 is provided for the growth of a semiconductor and may be formed of an insulating and conductive semiconductor material such as sapphire, Si, SiC, MgAl₂O₄, MgO, LiAlO₂, LiGaO₂, GaN, or the like. In this case, sapphire may be used, which has electrical insulation. Sapphire is a crystal having Hexa-Rhombo R3c symmetry, and has a lattice constant of 13.001 Å along a C-axis and a lattice constant of 4.758 Å along an A-axis. Orientation planes of the sapphire substrate include a C (0001) plane, an A (1120) plane, an R (1102) plane, and so one. In this case, the C plane is mainly used as a substrate for nitride growth because the C plane relatively facilitates the growth of a nitride thin film and is stable at relatively high temperatures. When the nitride thin film is grown on the C plane, a strong electrical field may be formed in the nitride thin film due to a piezoelectric effect. The substrate 101 may be a silicon (Si) substrate. Since the Si substrate is appropriate for obtaining a large diameter and has low manufacturing costs, mass production may be improved. When the Si substrate is used, a nucleation layer formed of a material such as AlₓGa₁₋ₓN (0≦x≦1) may be formed on the substrate 101 and then a nitride semiconductor having a required structure may be grown on the nucleation layer.

The n-type and p-type semiconductor layers 102 and 104 may be formed of a nitride semiconductor, for example, a material having a compositional formula of AlₓIn_{y}Ga_{1-x-y}N (0≦x≦1, 0≦y≦1, and 0≦x+y≦1). Each of the n-type and p-type semiconductor layers 102 and 104 may include a single layer or a plurality of layers having different properties such as doping concentrations, compositions, and so one. However, the n-type and p-type semiconductor layers 102 and 104 may be formed of an AlInGaP or AlInGaAs-based semiconductor other than a nitride semiconductor. The active layer 103 disposed between the n-type and p-type semiconductor layers 102 and 104 emits light having a predetermined amount of energy due to electron-hole recombination. As shown in FIG. 3, when the active layer 103 has a multiple quantum well (MQW) structure, for example, a nitride semiconductor in which quantum well layers 103a and quantum barrier layers 103b are alternately stacked on top of each other, the quantum well layers 103a may be formed of InGaN (the contents of In and Ga may be changed), and the quantum barrier layers 103b may include a region formed of GaN, InGaN (the contents of In and Ga may be changed and the content of In may be lower than in the quantum well layers 103a), AlInGaN (the contents of Al, In, and Ga may be changed), or the like.

The n-type and p-type semiconductor layers 102 and 104 and the active layer 103, which constitute a light emitting structure, may be grown by using a method that is known to the art, for example, metal organic chemical vapor deposition (MOCVD), hydride vapor phase epitaxy (HVPE), or molecular beam epitaxy (MBE). Although not illustrated, a buffer layer for relieving a stress applied to the n-type semiconductor layer 102 to increase the crystallinity of the n-type semiconductor layer 102 may be formed on the substrate 101 before the n-type semiconductor layer 102 is formed.

According to the present example, the p-type semiconductor layer 104 includes the electron blocking layer 104a and the clad layer 104b. As shown in FIG. 2, the electron blocking layer 104a may block electrons injected from the active layer 103 in order to increase recombination efficiency in the active layer 103. To this end, the electron blocking layer 104a may include a material having higher bandgap energy than a material of the clad layer 104b. In detail, as shown in FIG. 3, the electron blocking layer 104a includes first and second doping regions D1 and D2, wherein the first doping region D1 includes a region formed of AlₓIn_{y}Ga_{1-x-y}N (0<x≦1 and 0≦y<1), the second doping region D2 is formed of AlₐIn_{b}Ga_{1-a-b}N (0≦a<x and 0≦b≦1), and an energy bandgap of the first doping region D1 may be higher than the second doping region D2. For example, the first doping region D1 may be formed of AlGaN and the second doping region D2 may be formed of GaN.

As such, the electron blocking layer 104a may have a structure in which the first and second doping regions D1 and D2 having different energy bandgaps are alternately stacked one or more times, and particularly, may have a superlattice structure in which the first and second doping regions D1 and D2 having different energy bandgaps are alternately stacked two or more times. Due to the superlattice structure, an electron blocking function of the electron blocking layer 104a may be effectively ensured and a reduction in the crystallinity of the p-type semiconductor layer 104 may be prevented. In particular, according to the present example, the first and second doping regions D1 and D2 may be configured to include p-type impurities provided in different doping concentrations and p-type impurities of the second doping region D2 having relatively low bandgap energy may have a lower doping concentration. That is, the first doping region D1 may have a higher concentration of p-type impurities than that of the second doping region D2. In this case, during growth of the second doping region D2 having a relatively low doping concentration, the second doping region D2 may be doped with p-type impurities having a low concentration obtained by lowering a concentration of source gas or may be formed as an undoped region that is not intentionally doped.

According to the present example, the first and second doping regions D1 and D2 having different doping concentrations are alternately formed in the electron blocking layer 104a. Thus, particularly, holes may be effectively dispersed, which is particularly shown in the second doping region D2 having a relatively low doping concentration. In addition, the second doping region D2 that is appropriate for securing carriers due to having relatively low bandgap energy may have a further improved hole diffusion effect. Due to this configuration, current concentration may be significantly reduced during an operation of a semiconductor device. However, a doping concentration of a region having relatively low bandgap energy does not have to be low and the second doping region D2 having relatively small bandgap energy may have a higher doping concentration of p-type impurities than the first doping region D1. Although only two regions, that is, the first and second doping regions D1 and D2 having different doping concentrations, are formed, three or more doping regions having different doping concentrations, for example, an AlGaN/GaN/InGaN structure may be formed in the electron blocking layer 104a according to examples of the present application.

Although the first and second doping regions D1 and D2 facilitate dispersion of holes, it is difficult for p-type impurities, for example, magnesium (Mg), zinc (Zn), or the like to be diffused during the growth of the electron blocking layer 104a to obtain a required level of doping profile. That is, p-type impurities are diffused from the first doping region D1 having a high doping concentration to the second doping region D2 having a lower doping concentration during the growth of the electron blocking layer 104a or subsequent processes such that a doping concentration difference between the first and second doping regions D1 and D2 is lower than an intended difference. According to the present example, regions ‘C’ doped with n-type impurities, for example, silicon (Si), carbon (C), or the like, which are diffusion barrier regions ‘C’, may be formed on at least one of interfaces, for example, all interfaces between the first and second doping regions D1 and D2 in order to prevent p-type impurities from being diffused. In this case, the diffusion barrier regions ‘C’ may be doped with p-type impurities together with n-type impurities.

By forming the diffusion barrier regions ‘C’ on the interfaces between the first and second doping regions D1 and D2, p-type impurities may be prevented from being diffused across the interfaces so as to allow a doping profile close to a required doping profile to be obtained in the first and second doping regions D1 and D2. Thus, since a doping concentration difference in p-type impurities between the first and second doping regions D1 and D2 may be increased, a hole dispersion effect may be improved. In this case, a thickness of each diffusion barrier region ‘C’ may be appropriately determined by being doped with n-type impurities in consideration of a diffusion blocking effect or other electrical properties (for example, a driving voltage) and may be in the range of about 1 to about 100 Å. In addition, from a similar point of view, a concentration of n-type impurities of the diffusion barrier regions ‘C’ may be in the range of about 1.0×10¹⁶ to about 1.0×10²¹/cm³.

The clad layer 104b formed on the electron blocking layer 104a may be formed of a material having lower bandgap energy than that of a material of the electron blocking layer 104a, in particular, a material of the first doping region D1 having relatively great bandgap energy, as described above, but is not limited thereto. That is, when the first doping region D1 includes a region formed of AlₓIn_{y}Ga_{1-x-y}N (0<x≦1 and 0≦y<1) as described above, the clad layer 104b may include a region formed of AlₐIn_{b}Ga_{1-a-b}N (0≦a<x and 0≦b≦1), for example, p-GaN. A portion of the clad layer 104b, which contacts the ohmic electrode layer 105, may be doped to have a high doping concentration so as to form a contact region. In addition, the clad layer 104b may have a similar structure to the electron blocking layer 104a, in which regions having different doping concentration are alternately arranged, which will be described below with reference to FIG. 4.

Referring back to FIG. 1, the other components will be described below. The ohmic electrode layer 105 may be formed of a material that has electrical ohmic properties with respect to the p-type semiconductor layer 104 and may be formed of a transparent conductive oxide, which is selected from transparent electrode materials, having high light transmittance and relatively excellent ohmic contact performance, such as ITO, CIO, ZnO, or the like. Alternatively, the ohmic electrode layer 105 may be formed of a light reflective material, for example, a highly reflective metal. In this case, the semiconductor light emitting device 100 may have a flip-chip structure in which components are mounted toward a lead frame of a package of the first and second electrodes 106a and 106b. However, the ohmic electrode layer 105 may be optionally included in the present example and may be omitted if necessary.

The first and second electrodes 106a and 106b may be formed via a process of depositing or sputtering at least one conventional electro conductive material, for example, silver (Ag), aluminum (Al), nickel (Ni), chromium (Cr), or the like. However, in a structure shown in FIG. 1, the first and second electrodes 106a and 106b are formed on upper surfaces of the n-type semiconductor layer 102 and the ohmic electrode layer 105, respectively. However, FIG. 1 is merely an example of a method of forming the first and second electrodes 106a and 106b. That is, like in the example shown in FIG. 8, electrodes may be formed in various portions of a light emitting structure including the n-type semiconductor layer 302, the active layer 303, and the p-type semiconductor layer 304.

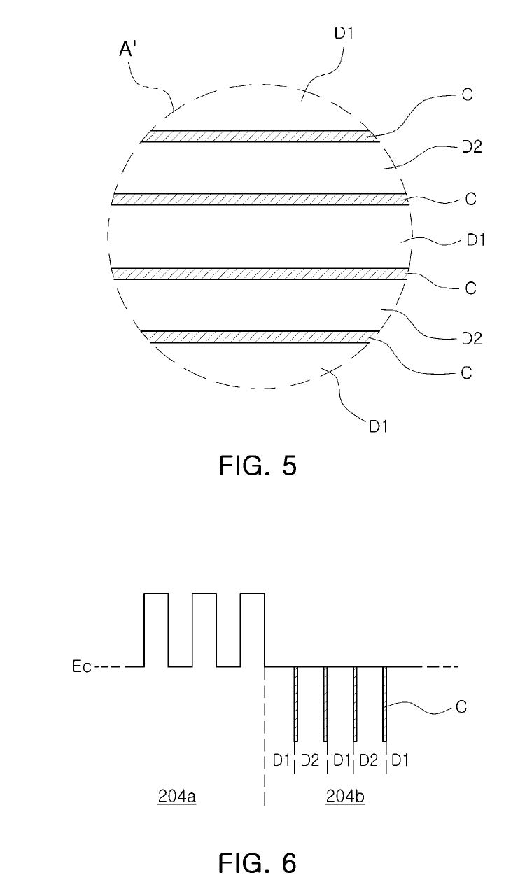

FIG. 4 is a schematic cross-sectional view of a semiconductor light emitting device 200 according to another example of the present application. FIG. 5 is an enlarged view of a clad layer 204b that may be used in the semiconductor light emitting device 200 of FIG. 4, according to an example of the present application. FIG. 6 is a diagram of an energy band around the clad layer 204b of FIG. 5, according to an example of the present application. Referring to FIG. 4, the semiconductor light emitting device 200 according to the present example includes a substrate 201, an n-type semiconductor layer 202, an active layer 203, a p-type semiconductor layer 204, and an ohmic electrode layer 205. First and second electrodes 206a and 206b may be formed on upper surfaces of the n-type semiconductor layer 202 and the ohmic electrode layer 205, respectively. In this case, the p-type semiconductor layer 204 may have a structure including an electron blocking layer 204a and the clad layer 204b.

The semiconductor light emitting device 200 is different from the semiconductor light emitting device 100 according to the above-described example in that the clad layer 204b includes the first and second doping regions D1 and D2 having different doping concentrations and diffusion barrier regions ‘C’ doped with n-type impurities (or n-type and p-type impurities) and formed on at least one interface between the first and second doping regions D1 and D2. In this case, the clad layer 204b may include regions having different bandgap energies, such as the electron blocking layer 104a according to the above-described example. Alternatively, as shown in FIG. 6, the clad layer 204b may have regions having the same amount of bandgap energy. That is, the first and second doping regions D1 and D2 may be formed of, for example, p-GaN and may have the same amount of bandgap energy. According to the present example, the electron blocking layer 204a may include a region formed of AlₓIn_{y}Ga_{1-x-y}N (0<x≦1 and 0≦y<1). The first and second doping regions D1 and D2 may include a region formed of AlₐIn_{b}Ga_{1-a-b}N (0≦a<x and 0≦b≦1) and may include a material having lower bandgap energy than that of the electron blocking layer 204a. In this case, the shape of the electron blocking layer 204a is not particularly limited and may have a structure the same as that of FIG. 1 or may have other structures that are known in the art, for example, a bulk structure, a superlattice structure, or the like.

According to the present example, the clad layer 204b may include the first and second doping regions D1 and D2 having different doping concentrations. Due to such modulation doping, a hole dispersion effect may be obtained. In particular, since a required doping profile of the clad layer 204b may be easily obtained by forming the diffusion barrier regions ‘C’ on one or more interfaces between the first and second doping regions D1 and D2, the hole diffusion effect may be further improved by increasing a doping concentration difference between the first and second doping regions D1 and D2. In this case, like in the above-described example, a thickness of each diffusion barrier region ‘C’ may be appropriately determined by being doped with n-type impurities in consideration of a diffusion blocking effect or other electrical properties (for example, a driving voltage) and may be in the range of about 1 to about 100 Å. In addition, from a similar point of view, a concentration of n-type impurities of the diffusion barrier regions ‘C’ may be in the range of about 1.0×10¹⁶ to about 1.0×10²¹/cm³.

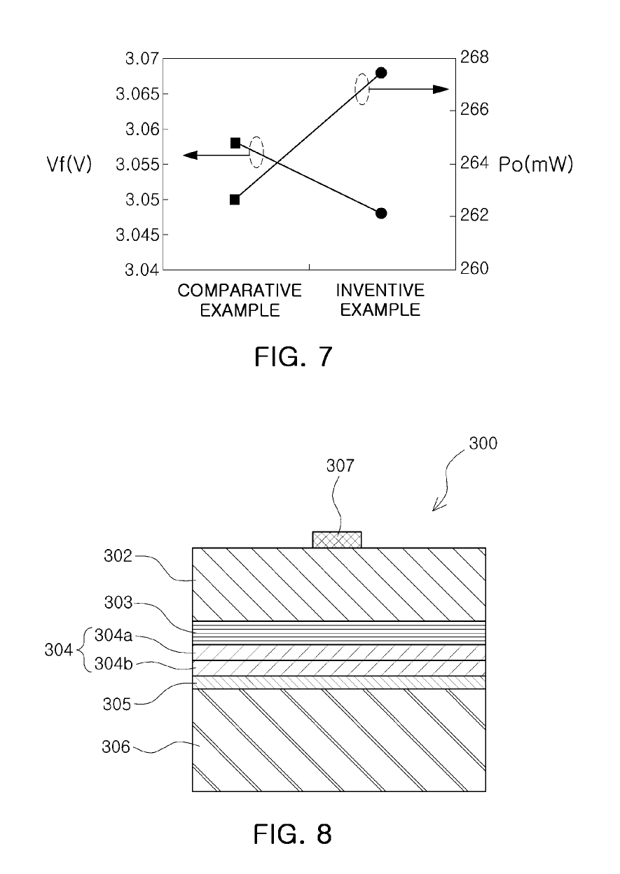

FIG. 7 is a graph showing a relationship between a driving voltage Vf and light emitting power Po, according to an inventive example and a comparative example. In the inventive example corresponding to the case of FIG. 1, the diffusion barrier regions ‘C’ are doped with Si and Mg. In the comparative example, the diffusion barrier regions ‘C’ are excluded from the structure shown in FIG. 1 and a doping concentration of an entire electron blocking layer is maintained to be constant. As shown in FIG. 7, when a modulation doping structure and a diffusion barrier region are used in an electron blocking layer, like in the inventive example, a driving voltage may be relatively lowered and light emitting power may be relatively increased. This result may indicate that a hole dispersion effect is improved.

FIG. 8 is a schematic cross-sectional view of a nitride semiconductor light emitting device 300 according to another example of the present application. In the nitride semiconductor light emitting device 300 according to the present example, a light emitting structure is formed on a conductive substrate 306 and includes an n-type semiconductor layer 302, an active layer 303, and a p-type semiconductor layer 304. In this case, the p-type semiconductor layer 304 may include an electron blocking layer 304a and a clad layer 304b and may have the structure that has been described in the above-described examples, thereby relieving current concentration.

An n-type electrode 307 may be formed on the n-type semiconductor layer 302. A reflective metal layer 305 and the conductive substrate 306 may be formed below the p-type semiconductor layer 304. The reflective metal layer 305 may be formed of a material that has electrical ohmic properties with respect to the p-type semiconductor layer 304 and may be formed of metal having high reflectivity so as to reflect light emitted from the active layer 303. In consideration of this function, the reflective metal layer 305 may be formed to contain silver (Ag), nickel (Ni), aluminium (Al), rhodium (Rh), palladium (Pd), iridium (Ir), ruthenium (Ru), magnesium (Mg), zinc (Zn), platinum (Pt), gold (Au), or the like.

The conductive substrate 306 may be connected to an external power source and may apply an electrical signal to the p-type semiconductor layer 304. In addition, the conductive substrate 306 may serve as a support for supporting the light emitting structure in a process for removing a substrate used for semiconductor growth, such as laser lift-off, and may be formed of a material including at least one of Au, Ni, Al, copper (Cu), tungsten (W), Si, selenium (Se), and GaAs. For example, a Si substrate may be doped with Al to form the conductive substrate 306. In this case, the conductive substrate 306 may be formed under the reflective metal layer 305 by using a process such as plating, sputtering, deposition, or the like. Alternatively, the conductive substrate 306 that is previously formed may be adhered to the reflective metal layer 305 by using a conductive adhesive layer as a medium.

As set forth above, according to examples of the present application, a semiconductor light emitting device may significantly reduce defects due to current concentration by obtaining an effect of dispersing holes in a lateral direction. However, the present application should not be construed as being limited to the effect described herein and may include objectives and effects that can be known from the detailed description although not clearly indicated.

While the foregoing has described what are considered to be the best mode and/or other examples, it is understood that various modifications may be made therein and that the subject matter disclosed herein may be implemented in various forms and examples, and that the teachings may be applied in numerous applications, only some of which have been described herein. It is intended by the following claims to claim any and all applications, modifications and variations that fall within the true scope of the present teachings.

What is claimed is:

1. A semiconductor light emitting device, comprising:
an n-type semiconductor layer;
a p-type semiconductor layer having a structure in which first and second doping regions including p-type impurities having different doping concentrations are alternately disposed one or more times; and
an active layer disposed between the n-type semiconductor layer and the p-type semiconductor layer,
the p-type semiconductor layer including at least one interface between the first and second doping regions, the at least one interface being doped with n-type impurities.

2. The semiconductor light emitting device of claim 1, wherein the first doping region has a higher doping concentration of p-type impurities than the second doping region.

3. The semiconductor light emitting device of claim 2, wherein the first doping region has a higher bandgap energy than the second doping region.

4. The semiconductor light emitting device of claim 3, wherein:
the first doping region includes a region formed of AlₓIn_{y}Ga_{1-x-y}N (0<x≦1 and 0≦y<1), and
the second doping region includes a region formed of AlₐIn_{b}Ga_{1-a-b}N (0≦a<x and 0≦b≦1).

5. The semiconductor light emitting device of claim 3, wherein the p-type semiconductor layer has a superlattice structure in which the first and second doping regions are alternately disposed two or more times.

6. The semiconductor light emitting device of claim 5, wherein:
the p-type semiconductor layer includes a clad layer having lower bandgap energy than the first doping region, and
the superlattice structure is disposed between the active layer and the clad layer.

7. The semiconductor light emitting device of claim 6, wherein:
the first doping region includes a region formed of AlₓIn_{y}Ga_{1-x-y}N (0<x≦1 and 0≦y<1), and
the clad layer includes a region formed of AlₐIn_{b}Ga_{1-a-b}N (0≦a<x and 0≦b≦1).

8. The semiconductor light emitting device of claim 2, wherein the first and second doping regions have the same amount of bandgap energy.

9. The semiconductor light emitting device of claim 8, wherein the p-type semiconductor layer includes:
an electron blocking layer that is disposed to be adjacent to the active layer and has a higher bandgap energy than the first and second doping regions.

10. The semiconductor light emitting device of claim 9, wherein:
the electron blocking layer includes a region formed of AlₓIn_{y}Ga_{1-x-y}N (0<x≦1 and 0≦y<1), and
the first and second doping regions include a region formed of AlₐIn_{b}Ga_{1-a-b}N (0≦a<x and 0≦b≦1).

11. The semiconductor light emitting device of claim 2, wherein the second doping region includes p-type impurities and is not intentionally doped.

12. The semiconductor light emitting device of claim 1, wherein the interface between the first and second doping regions is further doped with p-type impurities.

13. The semiconductor light emitting device of claim 1, wherein:
the n-type impurities include at least one of silicon (Si) and carbon (C), and
the p-type impurities include at least one of magnesium (Mg) and zinc (Zn).

14. A semiconductor light emitting device, comprising:
a first type semiconductor layer;
a second type semiconductor layer having a structure in which first and second doping regions including second type impurities provided in different doping concentrations are alternately disposed one or more times with a diffusion barrier region disposed at an interface between the first and second doping regions to prevent diffusion of the second type impurities; and
an active layer disposed between the first type semiconductor layer and the second type semiconductor layer.

15. The semiconductor light emitting device of claim 14, wherein the first doping region has a higher doping concentration of second type impurities than the second doping region.

16. The semiconductor light emitting device of claim 15, wherein the first doping region has a higher bandgap energy than the second doping region.

17. The semiconductor light emitting device of claim 16, wherein:
the first doping region includes a region formed of AlₓIn_{y}Ga_{1-x-y}N (0<x≦1 and 0≦y<1), and
the second doping region includes a region formed of AlₐIn_{b}Ga_{1-a-b}N (0≦a<x and 0≦b≦1).

18. The semiconductor light emitting device of claim 17, wherein the second type semiconductor layer has a superlattice structure in which the first and second doping regions are alternately disposed two or more times.

19. The semiconductor light emitting device of claim 14, further comprising a reflective metal layer disposed on the second type semiconductor layer.

20. The semiconductor light emitting device of claim 14, wherein the diffusion barrier region includes first type impurities.
